(19) United States
(12) Patent Application Publication
(10) Pub. No.: US 2007/0164790 A1
(43) Pub. Date: Jul. 19, 2007

(54) Method for Forming a Domino Circuit

(76) Inventor: Tzu-Pin Shen, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/306,894

(22) Filed: Jan. 16, 2006

(51) Int. Cl. H03K 19/096

(52) U.S. Cl. 326/95

(57) ABSTRACT

A method for forming a domino circuit includes forming a pre-charge circuit in a basic unit positioned on a semiconductor body of an integrated circuit, forming elements of a pull down network circuit in the basic unit, and forming a metal layer upon the semiconductor body for routing the elements of the pull down network circuit for programming the pull down network circuit to be capable of performing a logic operation.

### BACKGROUND OF THE INVENTION

1. Field of the Invention

The present invention relates to a method for forming a domino circuit, and more particularly, to a method for forming the domino circuit by means of a metal programmable semiconductor process.

2. Description of the Prior Art

A domino circuit is a type of dynamic circuit, which includes a pre-charge phase and an evaluation phase for preventing an unrecoverable glitch. The domino circuit can perform a logic function and is usually combined with other domino circuits for performing a complex logic function, such as decoding, switching, etc. In the prior art, logic functions of each stage of the domino circuits are fixed, so that when modifying the logic functions, it is necessary to do a full layer photomask change, which is time-consuming.

Please refer to FIG. 1, which illustrates a schematic diagram of a prior art domino circuit 100. A pull down network circuit 102 in the domino circuit 100 is performing a logic function at the evaluation phase. The pull down network circuit 102 includes a transistor array composed of a plurality of transistors. Among the transistors are inter-connections and routings for coupling the transistors to perform the logic function. The logic function is fixed, and is only changed by changing a photomask pattern of the pull down network circuit 102. Therefore, if a designer wants to modify the logic function of the pull down network circuit 102, the designer can only change the photomask pattern to redesign the logic function. However, with the speedy development of the semiconductor process, the width of routings becomes narrower, so the required photomask pattern demands greater precision. In other words, the photomask cost substantially increases owing to advances in the semiconductor process. Therefore, production cost and redesign time of the prior art domino circuit design certainly increases. The market competitiveness of the domino circuit is therefore weakened.

### SUMMARY OF THE INVENTION

It is therefore a primary objective of the claimed invention to provide a method for forming a domino circuit.

The present invention discloses a method for forming a domino circuit. The method includes forming a pre-charge circuit in a basic unit positioned on a semiconductor body of an integrated circuit, forming elements of a pull down network circuit in the basic unit, and forming a metal layer upon the semiconductor body for routing the elements of the pull down network circuit for programming the pull down network circuit to be capable of performing a logic operation.

The present invention further discloses a method for forming a pull down network circuit of a domino circuit. The method includes forming elements of the pull down network circuit in a basic unit positioned on a semiconductor body of an integrated circuit, and forming a metal layer upon the semiconductor body for routing the elements of the pull down network circuit for programming the pull down network circuit to be capable of performing a logic operation.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a prior art domino circuit.

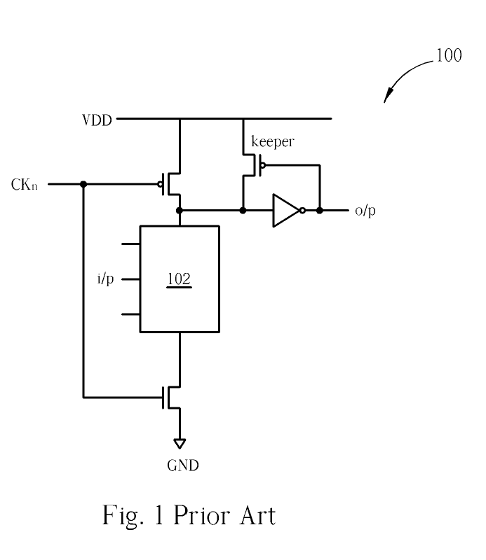

FIG. 2 illustrates a flowchart of a process for forming a domino circuit in accordance with the present invention.

FIG. 3 illustrates a schematic diagram of a domino circuit.

FIG. 4 illustrates a schematic diagram of a layout of a pull down network circuit in FIG. 3.

FIG. 5 illustrates a schematic diagram of a domino circuit.

FIG. 6 illustrates a schematic diagram of a layout of a pull down network circuit in FIG. 5.

### DETAILED DESCRIPTION

The present invention forms a domino circuit by means of a metal programmable semiconductor process, which is described as follows. First, a semiconductor foundry forms an integrated circuit having a plurality of basic units in a semiconductor body in advance. At least a logic operation module with programmable nodes is positioned within each basic unit. Therefore, for the logic operation module, an integrated circuit designer only needs to design one photomask pattern to program the functionality of the logic operation module. On a metal layer, the semiconductor foundry forms routings required to implement the functionality of the logic operation module according to the photomask pattern defined by the integrated circuit designer.

Then, the contacts corresponding to programmable nodes are positioned at a fewer amounts of horizontal tracks, so the metal layers have more space to allocate routings between different basic units. In other words, fewer photomasks are used during the semiconductor process for fabricating the integrated circuit. Therefore, the production cost of the integrated circuit is greatly reduced.

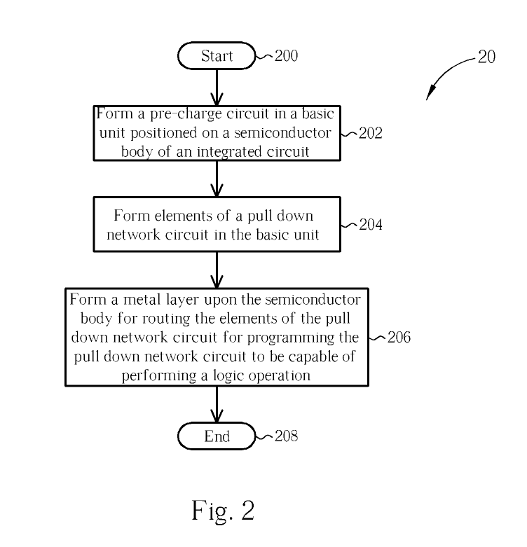

Please refer to FIG. 2, which illustrates a flowchart of a process 20 in accordance with the present invention. The process 20 is utilized for forming a domino circuit, and includes following steps:

Step 200: Start.

Step 202: Form a pre-charge circuit in a basic unit positioned on a semiconductor body of an integrated circuit.

Step 204: Form elements of a pull down network circuit in the basic unit.

Step 206: Form a metal layer upon the semiconductor body for routing the elements of the pull down network circuit for programming the pull down network circuit to be capable of performing a logic operation.

Step 208: End.

According to the process 20, when forming a domino circuit, the present invention forms routings of a pull down network circuit of the domino circuit with the metal programmable semiconductor process, which uses one metal layer for routing elements of the pull down network circuit to program the pull down network circuit to be capable of performing a logic operation. Therefore, if a designer wants to change the logic operation, the designer only needs to change the metal layer, which is an efficient way to make the change.

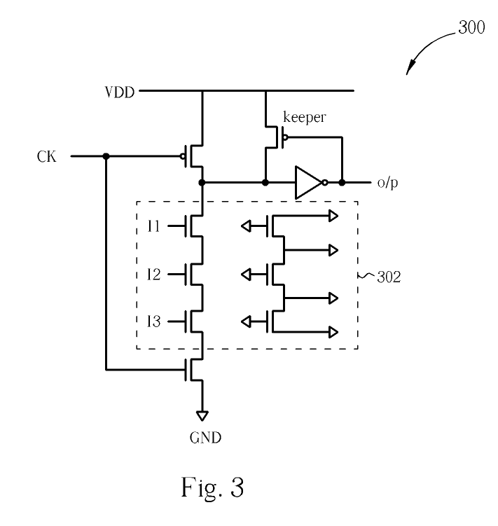

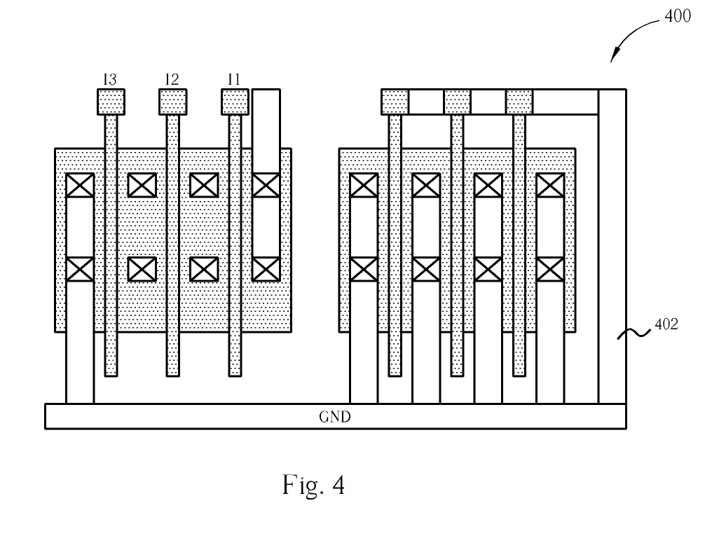

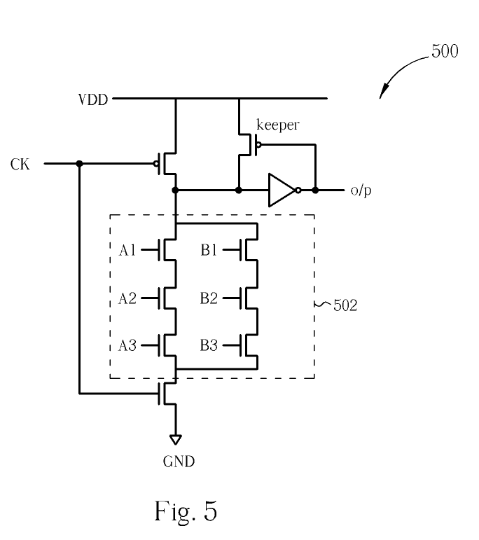

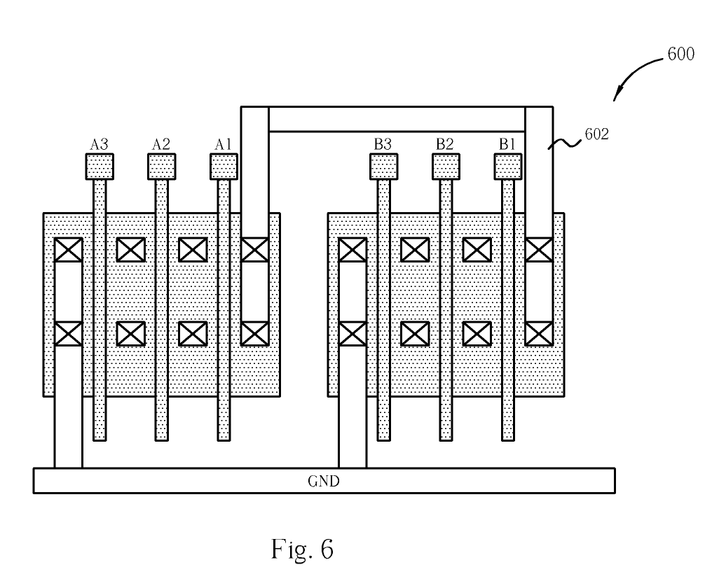

For example, please refer to FIG. 3 to FIG. 6. FIG. 3 illustrates a schematic diagram of a domino circuit 300. A pull down network circuit 302 of the domino circuit 300 includes a transistor array composed of a plurality of transistors for performing a logic function. FIG. 4 illustrates a schematic diagram of a layout 400 of the pull down network circuit 302. The logic function of the pull down network circuit 302 is formed by a metal connection 402. FIG. 5 illustrates a schematic diagram of another domino circuit 500. A pull down network circuit 502 of the domino circuit 500 includes a transistor array composed of a plurality of transistors for performing a logic function. FIG. 6 illustrates a schematic diagram of a layout 600 of the pull down network circuit 502. The logic function of the pull down network circuit 502 is formed by a metal connection 602. According to the process 20, if a designer wants to change the logic function of the pull down network circuit 302 to that of the pull down network circuit 502, the designer only needs to change the metal connection 402 to the metal connection 602.

In summary, the present invention can modify the logic function of the pull down network circuit by changing metal connections between the transistors in the pull down network circuit. Therefore, the present invention does not need to perform a full layer photomask modification when changing the logic function, so that design flexibility is increased and the design cycle time can be widened. The mask cost for function modification can be saved, and the time to market can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a domino circuit comprising:
forming a pre-charge circuit in a basic unit positioned on a semiconductor body of an integrated circuit;
forming elements of a pull down network circuit in the basic unit; and
forming a metal layer upon the semiconductor body for routing the elements of the pull down network circuit for programming the pull down network circuit to be capable of performing a logic operation.

2. The method of claim 1 further comprising adjusting a photomask pattern of the metal layer when the logic operation is changed.

3. A domino circuit implementing the method of claim 1.

4. A method for forming a pull down network circuit of a domino circuit comprising:
forming elements of the pull down network circuit in a basic unit positioned on a semiconductor body of an integrated circuit; and
forming a metal layer upon the semiconductor body for routing the elements of the pull down network circuit for programming the pull down network circuit to be capable of performing a logic operation.

5. The method of claim 4 further comprising adjusting a photomask pattern of the metal layer when the logic operation is changed.

6. A pull down network circuit of a domino circuit implementing the method of claim 4.
